(19) United States
(12) Patent Application Publication
(10) Pub. No.: US 2017/0059710 A1
(43) Pub. Date: Mar. 2, 2017

(54) OBJECT RECOGNITION DEVICE

(71) Applicant: Robert Bosch GmbH, Stuttgart (DE)

(72) Inventors: Christoph Delfs, Bretten (DE); Frank Fischer, Gomaringen (DE); Reiner Schnitzer, Reutlingen (DE); Heiko Ridderbusch, Schwieberdingen (DE); Gael Pilard, Wankheim (DE)

(21) Appl. No.: 15/306,205

(22) PCT Filed: Mar. 3, 2015
(86) PCT No.: PCT/EP2015/054377

§ 371 Date: Oct. 24, 2016

(30) Foreign Application Priority Data
Apr. 28, 2014 (DE) 10 2014 207 965.9

(51) Int. Cl. G01S 17/42; H01S 5/183; G01S 17/32; G01S 7/481; G01S 17/58

(52) U.S. Cl. CPC G01S 17/42; G01S 7/4817; G01S 17/58; G01S 17/32; H01S 5/183

(57) ABSTRACT

An object recognition device having a VCSEL Doppler sensor and an MEMS scanner; the MEMS scanner having at least one deflectable MEMS mirror for scanning an angular region using a laser beam from the VCSEL Doppler sensor; the VCSEL Doppler sensor being connected to a Doppler control and evaluation element that is adapted for determining the velocity and/or the distance of an object.

### BACKGROUND INFORMATION

The document “VCSEL-based miniature laser-Doppler interferometer,” A. Pruijmboom et al., Proc. of SPIE, vol. 6908 describes an integrated Doppler sensor where a VCSEL and a photodiode are integrated on a common semiconductor substrate. VCSEL Doppler sensors are already used in high-resolution computer mice. VCSEL Doppler sensors measure the relative velocity of a reflecting object and the distance thereof (in modulated operation). Alternatively, instead of VCSEL, VeCSEL (VCSEL having an external cavity) can also be used. MEMS mirrors or micromirrors, as well as laser scanner projectors having such MEMS mirrors are also available in the related art.

### SUMMARY

It is an object of the present invention to provide a compact and inexpensive object recognition device that can be used, for example, for recognizing gestures on a plane surface, such as a computer mouse, touch screen or wall switch, for example.

The present invention relates to an object recognition device having a VCSEL Doppler sensor and an MEMS scanner; the MEMS scanner having at least one deflectable MEMS mirror for scanning an angular region using a laser beam from the VCSEL Doppler sensor; the VCSEL Doppler sensor being connected to a Doppler control and evaluation element that is adapted for determining the velocity and/or the distance of an object. This device may be advantageously used to scan an angular region for objects. The device is advantageously very energy efficient.

An advantageous embodiment of the present invention provides that the VCSEL Doppler sensor have a laser and a photodiode that are monolithically integrated. This embodiment is especially compact and inexpensive.

An advantageous embodiment of the present invention provides that the VCSEL Doppler sensor have a laser having an external cavity, namely a VeCSEL.

An advantageous embodiment of the present invention provides that the device feature a scanner control and position recognition element that is linked to the MEMS scanner and is adapted for determining the angular position of the MEMS mirror. The location of the object is thereby able to be determined in polar coordinates, for example. It is especially advantageous that the device have a synchronization unit that is linked to the Doppler control and evaluation element and to the scanner control and position recognition element, and that it be adapted for determining the velocity and/or distance of the object in a time- and angle-resolved manner.

The structure of the scanned surface of the object may also be advantageously determined when working with an appropriate object size and resolving power of the object recognition device. An advantageous embodiment of the present invention provides that the MEMS scanner have an MEMS mirror that is deflectable in two different axes of rotation or two MEMS mirrors that are deflectable in different axes of rotation for scanning a solid angle region. To recognize objects or gestures, scanning is advantageously carried out using one or a plurality of laser beams generally parallel to an operating interface. For this, one or a plurality of micromirrors employing MEMS technology is/are used. The present invention provides that the laser beam be produced by a VCSEL (vertical cavity surface emitting laser) or a VeCSEL (vertical external-cavity surface-emitting laser) that is part of a Doppler sensor. In the case of a VCSEL Doppler sensor, (infrared) laser radiation is emitted by a VCSEL. If an object backscatters a portion of the laser light (up to 10⁻⁶ of the power output), photons are coupled into the cavity of the VCSEL and, there, constructively or destructively superpose the stationary wave of the stimulated emission. This changes the output signal. The power output of the VCSEL is directly measured by a monolithically integrated photodiode. An especially compact and cost-saving configuration is provided here by monolithically integrating the photodiode with the VCSEL in a very small, inexpensive component. It is also advantageous that the mirror structure of the VCSEL (multiple semiconductor layers) be a very narrow-band structure for the transmission of light, that it thereby filter out ambient light, and, in principle, that it only carry the coherent photons of the emission thereof to produce a superimposition effect, thereby achieving a very high sensitivity.

The power output begins to oscillate when the scattering object moves toward the laser or away therefrom (Doppler effect). In the case of a modulated operation of the VCSEL Doppler sensor, besides the velocity, the distance to the reflecting surface may also be determined.

The Gaussian beam geometry of the VCSEL advantageously makes it possible for a simple wafer level collimation optics to be used. The VCSEL Doppler sensor advantageously has a high sensitivity. Moreover, it is very insensitive to background light and temperature fluctuations. For that reason, the device according to the present invention makes do with very little reflected light and may be used under a variety of even unfavorable environmental conditions.

### BRIEF DESCRIPTION OF THE DRAWINGS

FIG. 1 schematically shows an object recognition device according to the present invention.

FIG. 2 illustrates the operating principle of the object recognition device according to the present invention.

### DETAILED DESCRIPTION OF EXAMPLE EMBODIMENTS

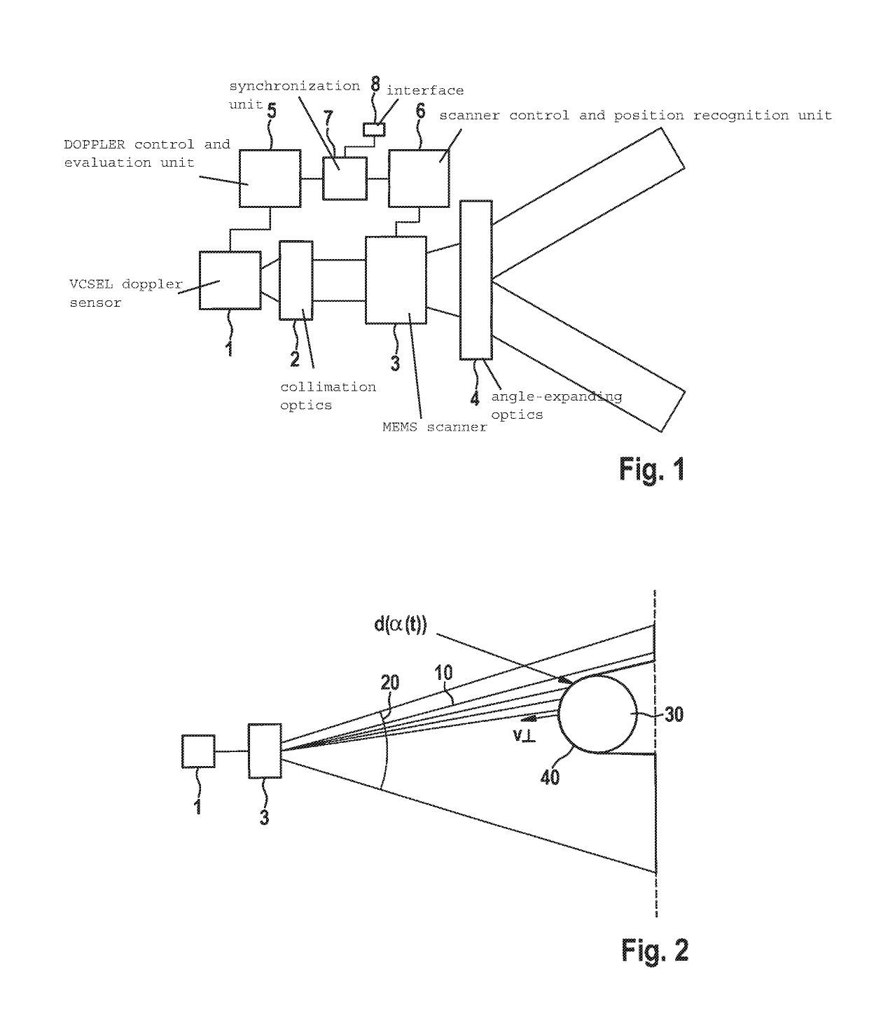

FIG. 1 schematically shows an object recognition device according to the present invention. A VCSEL Doppler sensor 1 having collimation optics 2 transmits a laser beam 10, for example in infrared radiation, to an MEMS scanner 3. MEMS scanner 3 is essentially composed of one or a plurality of MEMS mirrors, whose position is measured by an integrated position recognition element (not shown). Behind MEMS scanner 3, an angle-expanding optics 4 may optionally be used that may be designed, for example, as a lens optics or of a concave (for example, cylindrical) mirror (in the reflection). The purpose of the beam expansion is to enlarge the scanning angle of the mirror to broaden the region for capturing the object. As needed, the mirror itself may also be alternatively operated at higher amplitudes. VCSEL Doppler sensor 1 is connected to a Doppler control and evaluation unit 5. MEMS scanner 3 is connected to a scanner control and position recognition unit 6. The device optionally features a synchronization unit 7 that is connected to Doppler control and evaluation unit 5 and scanner control and position recognition unit 6. Thus, the evaluation signal from the Doppler sensor, i.e., the velocity or also distance of a detected object and the corresponding angular position of mirror module 3 may be determined in a time-resolved manner. An evaluated positional signal indicative of the objector also raw data sets may be transmitted via an interface 8 to an application processor. Units 5, 6 and 7 may also be integrated in a circuit element.

FIG. 2 illustrates the operation of the object recognition device according to the present invention. Shown here exemplarily is a one-dimensional scanner that scans parallel to a user interface, such as a table surface or a sheet plane. Scanned angular region 20 is determined by the possible deflection range of the MEMS mirror in MEMS scanner 3. Also shown exemplarily are individual laser beams 10 that are transmitted at an angle α(t). At distance d(α(t)), laser beams 10 strike next reflecting surface 40 of an object 30. Outside of object 30, a background signal is shown in simplified form as a plane. A Doppler sensor is able to ascertain distance d. Besides distance d, velocity v may also be alternatively determined. If the object velocity is measured quickly relative to the scanner velocity, it is possible to measure the movement of the object toward the scanner. Using such an object recognition device, it is possible to detect finger movements, for example, simple or even corresponding complex gestures on the user interface, or closely thereabove. For that purpose, the object recognition device is positioned on the user interface, for example on the table surface or otherwise suitably fastened thereto or thereabove. This is accomplished in that the scanner scans thereover generally parallel to the user interface in a grazing process or a few millimeters to centimeters thereabove.

Moreover, object recognition devices are also possible where MEMS scanner 3 features an MEMS mirror that is deflectable in two different axes of rotation or two MEMS mirrors that are deflectable in different axes of rotation. This provides a scanning of a solid angle region.

1-6. (canceled)

7. An object recognition device, comprising:
a VCSEL Doppler sensor; and
a MEMS scanner, the MEMS scanner having at least one deflectable MEMS mirror for scanning an angular region using a laser beam from the VCSEL Doppler sensor, the VCSEL Doppler sensor being connected to a Doppler control and evaluation element that is adapted for determining at least one of a velocity of an object and a distance of the object.

8. The object recognition device as recited in claim 7, wherein the VCSEL Doppler sensor has a laser and a photodiode that are monolithically integrated.

9. The object recognition device as recited in claim 8, wherein the VCSEL Doppler sensor has a laser having an external cavity, the laser being a VeCSEL.

10. The object recognition device as recited in claim 7, wherein the device has a scanner control and position recognition element that is linked to the MEMS scanner and is adapted for determining the angular position of the MEMS mirror.

11. The object recognition device as recited in claim 7, wherein the device has a synchronization unit that is linked to the Doppler control and evaluation element and to the scanner control and position recognition element, and that is adapted for determining the at least one of the velocity of the object and the distance of the object, in a time- and angle-resolved manner.

12. The object recognition device as recited in claim 7, wherein the MEMS scanner has one of: i) a MEMS mirror that is deflectable in two different axes of rotation, or ii) two MEMS mirrors that are deflectable in different axes of rotation for scanning a solid angle region.
